(19) United States
(12) Patent Application Publication
(10) Pub. No.: US 2016/0276399 A1
(43) Pub. Date: Sep. 22, 2016

(54) PHOTODETECTOR

(71) Applicant: KABUSHIKI KAISHA TOSHIBA, Tokyo (JP)

(72) Inventors: Masaki ATSUTA, Yokosuka (JP); Keita SASAKI, Yokohama (JP); Hitoshi YAGI, Yokohama (JP); Kazuhiro ITSUMI, Tokyo (JP); Rei HASEGAWA, Yokohama (JP)

(21) Appl. No.: 14/950,728

(22) Filed: Nov. 24, 2015

(30) Foreign Application Priority Data
Mar. 16, 2015 (JP) 2015-052590

(51) Int. Cl. H01L 27/146

(52) U.S. Cl. CPC H01L 27/14663; H01L 27/14636

(57) ABSTRACT

According to an embodiment, a photodetector includes a photodetecting element and first electrodes. In the photodetecting element, a plurality of pixel regions including a plurality of photodetection portions that detects light are arrayed on a first plane on which the light is incident. The first electrodes pass through a first layer including the photodetection portions in a second direction intersecting with the first plane. The first electrodes are provided respectively corresponding to the pixel regions arranged in an edge area of the first plane of the photodetecting element. The first electrodes are each arranged such that at least a part of a region thereof is arranged outside of the corresponding pixel region.

### CROSS-REFERENCE TO RELATED APPLICATIONS

This application is based upon and claims the benefit of priority from Japanese Patent Application No. 2015-052590, filed on Mar. 16, 2015; the entire contents of which are incorporated herein by reference.

### FIELD

Embodiments described herein relate generally to a photodetector.

### BACKGROUND

There is known a photodetecting element in which a plurality of avalanche photodiodes (APDs) are arranged in a single pixel region. As a representative example, a silicon photomultiplier (SiPM) using silicon diodes as APDs is known.

Furthermore, there is disclosed a device in which a plurality of combinations, each having a plurality of APDs and a scintillator that converts X-rays into scintillation light, are arranged. By thus combining APDs and a scintillator, an image having a spatial resolution according to the size of the scintillator can be obtained using photo-counting technique. For example, there is also known a technique for obtaining a CT (Computed Tomography) image by detecting X-rays.

In a photodetector provided with the SiPM, signals detected in the respective pixel regions are output to a signal processing circuit via signal lines. Thus, a multi-line CT apparatus requires the signal lines corresponding to the number of pixel regions. Because the number of signal lines increases as a higher resolution is achieved, the area of a pixel region needs to be smaller. However, the light-receiving area, in which the APDs receive light, included in the pixel region decreases as the area of the pixel region becomes smaller. Thus, the technologies to prevent the light-receiving area from decreasing, that is, a method of connecting each signal electrode of respective pixel regions to a through-hole electrode and a technique of arranging photodetecting elements, in which a plurality of pixel regions are arrayed, in a planar filling manner along a plane of incidence of light, have been disclosed.

In a circumferential edge area of the photodetecting element, however, there are regions in which the APD cannot be provided. Thus, out of a plurality of pixel regions provided on the photodetecting element, the pixel regions arranged along the circumferential edge of the photodetecting element are smaller in size compared with the other pixel regions. As the pixel region becomes smaller, the number of APDs included in the pixel region becomes fewer. Thus, the dynamic range is reduced, which has been a problem.

### BRIEF DESCRIPTION OF THE DRAWINGS

FIG. 1 is a schematic diagram illustrating an example of an inspection apparatus;

FIGS. 2A and 2B are explanatory diagrams of a photodetecting element;

FIG. 3 is a plan view of the photodetecting element;

FIG. 4 is a schematic diagram in which a part of the photodetecting element is enlarged;

FIG. 5 is a schematic diagram illustrating an example of a cross-sectional view of the photodetecting element;

FIG. 6 is a schematic diagram illustrating one example of a conventional photodetecting element;

FIGS. 7A and 7B are comparison diagrams between the conventional photodetecting element and the photodetecting element according to an embodiment;

FIG. 8 is a schematic diagram illustrating a terminal portion S;

FIGS. 9A and 9B are explanatory charts illustrating electrical characteristics of the photodetecting elements;

FIG. 10 is a schematic diagram of a photodetector; and

FIG. 11 is a plan view of the photodetecting element.

### DETAILED DESCRIPTION

According to an embodiments a photodetector includes a photodetecting element and first electrodes. In the photodetecting element, a plurality of pixel regions including a plurality of photodetection portions that detects light are arrayed on a first plane on which the light is incident. The first electrodes pass through a first layer including the photodetection portions in a second direction intersecting with the first plane. The first electrodes are provided respectively corresponding to the pixel regions arranged in an edge area of the first plane of the photodetecting element. The first electrodes are each arranged such that at least a part of a region thereof is arranged outside of the corresponding pixel region.

Various embodiments will be described in detail below with reference to the accompanying drawings.

### First Embodiment

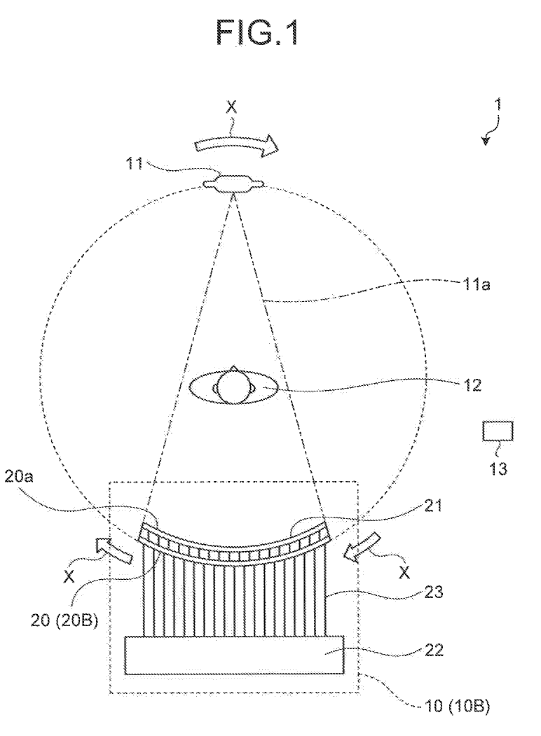

FIG. 1 is a schematic diagram illustrating an example of an inspection apparatus 1 according to a first embodiment.

The inspection apparatus 1 includes a light source 11, a photodetector 10, and a drive unit 13. The light source 11 and the drive unit 13 are electrically connected to the photodetector 10.

The light source 11 and the photodetector 10 are arranged facing each other with spacing therebetween. A subject 12 to be inspected is disposed between the photodetector 10 and the light source 11. The light source 11 and the photodetector 10 are provided so as to be rotatable about the subject 12 with the their facing disposition state maintained.

The light source 11 emits radiation 11a such as X-rays toward the photodetector 10 facing the light source 11. The radiation 11a emitted from the light source 11 passes through the subject 12 placed on a gantry not illustrated and is enters the photodetector 10.

The photodetector 10 is a device that detects light. The photodetector 10 includes a plurality of photodetecting elements 20 and a signal processing circuit 22. The photodetecting elements 20 and the signal processing circuit 22 are electrically connected to each other. In the first embodiment, the plurality of photodetecting elements 20 provided in the photodetector 10 are arrayed along a rotational direction (an arrow X direction in FIG. 1) of the photodetector 10.

The photodetecting elements 20 receive the radiation 11a that is emitted from the light source 11 and passing through the subject 12 with a first plane 20a thereof through a collimator 21. The first plane 20a is a two-dimensional plane of the photodetecting elements 20, on which the light is incident.

The collimator 21 is placed on the first plane 20a side of the photodetecting elements 20, and prevents scattered light from entering the photodetecting elements 20.

The photodetecting elements 20 detect the received light. Then, the photodetecting elements 20 output photocurrents corresponding to the detected light (hereinafter, referred to as signals) to the signal processing circuit 22 via signal lines 23. The signal processing circuit 22 controls a whole of the inspection apparatus 1. The signal processing circuit 22 acquires the signals from the photodetecting elements 20.

In the first embodiment, the signal processing circuit 22 calculates the energies and intensities of the radiation entering the respective photodetecting elements 20, based on the current values of the acquired signals. Then, the signal processing circuit 22 generates an image of the subject 12 based on radiation information from the energies and intensities of the radiation entering the respective photodetecting elements 20.

The drive unit 13 allows the light source 11 and the photodetector 10 to rotate about the subject 12 positioned between the light source 11 and the photodetector 10, with their facing state maintained. This configuration enables the inspection apparatus 1 to generate tomographic images of the subject 12.

The subject 12 is a human body, for example. The subject 12, however, is not limited to human bodies. The subject 12 may be animals, plants, or nonliving material such as articles. That is, the inspection apparatus 1 is applicable not only as inspection apparatuses for generating tomographic images of human bodies, animals and plants, but also as various types of inspection apparatuses such as security apparatuses for seeing through articles.

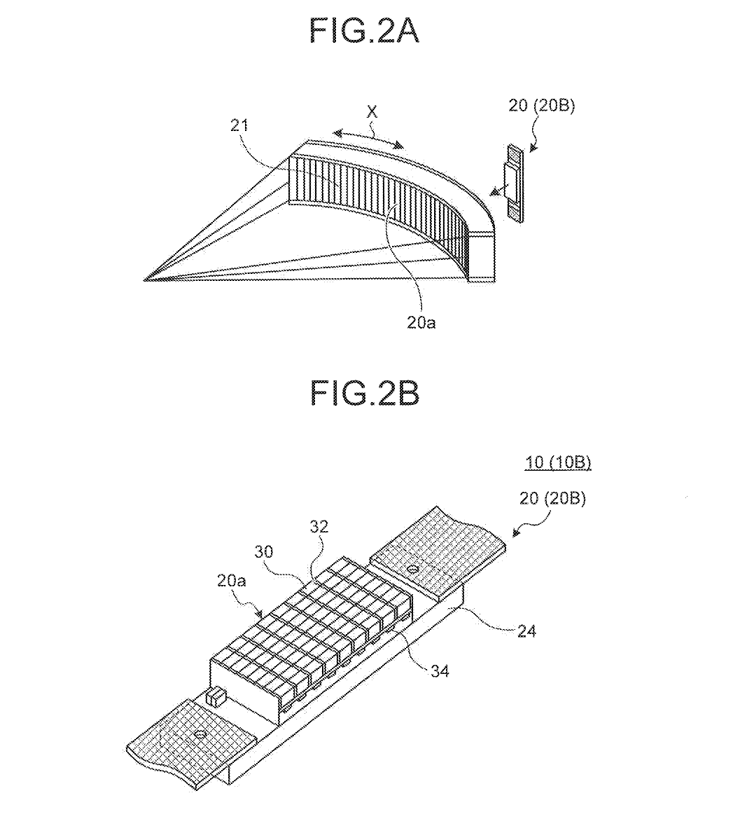

FIGS. 2A and 2B are explanatory diagrams of the photodetecting elements 20. FIG. 2A is a diagram illustrating an arrangement state of the plurality of photodetecting elements 20. The plurality of photodetecting elements 20 are arranged in a substantially arc shape in the rotational direction of the photodetecting elements 20 (see an arrow X in FIG. 2A). In other words, the plurality of photodetecting elements 20 are arranged in a planar filling (tiling) manner along the first plane 20a that is a light incident surface.

FIG. 2B is a schematic diagram of the photodetecting element 20. The photodetecting element 20 includes photodetection portions 34 on a supporting substrate 24.

The photodetection portion 34 detects light. The photodetecting element 20 is a silicon photomultiplier (SiPM) in which a plurality of avalanche photodiodes (APDs) are arranged as photodetection portions 34. The APD is a known avalanche photodiode.

The photodetection portion 31 may include a scintillator on the light incident side.

The scintillator converts radiation into light (photons) having a longer wavelength than that of the radiation. The scintillator is made of a scintillator material. The scintillator material emits fluorescence (scintillation light) by the incidence of radiation such as X-rays. The scintillator material is selected as appropriate, according to the application target of the photodetector 10. The scintillator material is, for example, Lu₂SiO₅:(Ce), LaBr₃:(Ce), yttrium aluminum perovskite (YAP):Ce, or Lu(Y)AP:Ce, but is not limited thereto.

The photodetecting element 20 is configured such that a plurality of photodetection portions 34 serve as one pixel region 30 and a plurality of pixel regions 30 are arranged. The region other than the pixel regions 30 on the first plane 20a is a peripheral region 32 that is the surrounding of the pixel regions 30.

When light is incident on the first plane 20a of the photodetecting element 20, the photodetection portions 34 provided in the respective pixel regions 30 detect the energy and intensity of the incident light for each pixel region 30.

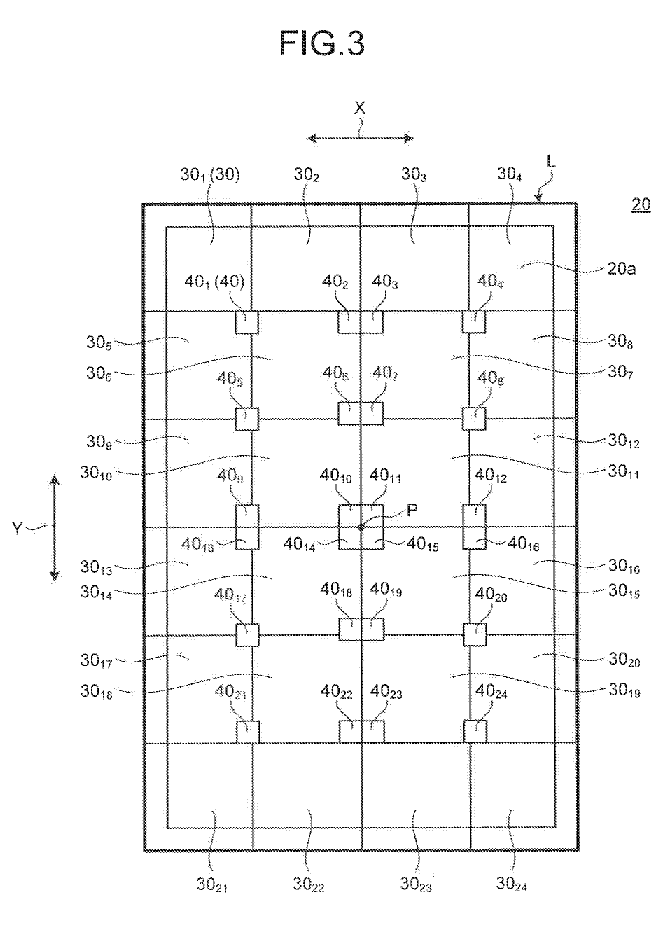

FIG. 3 is one example of a plan view of the photodetecting element 20 viewed from the first plane 20a side. Illustrated in FIG. 3 is, as an example, the photodetecting element 20 including 24 pieces of the pixel regions 30 in which 4 pixels (4 pieces of the pixel regions 30) are arrayed in an arrow X direction on the first plane 20a and 6 pixels (6 pieces of the pixel regions 30) are arrayed in an arrow Y direction. The number of pieces of the pixel regions 30 included in the photodetecting element 20 is not limited to 24 pieces.

As illustrated in FIG. 3, the respective pixel regions 30 (pixel region 30₁ to pixel region 30₂₄) are arrayed in a matrix form along the first plane 20a (see the arrow X direction and the arrow Y direction in FIG. 3). The term “being arrayed in a matrix form” means being arrayed in a row direction and a column direction.

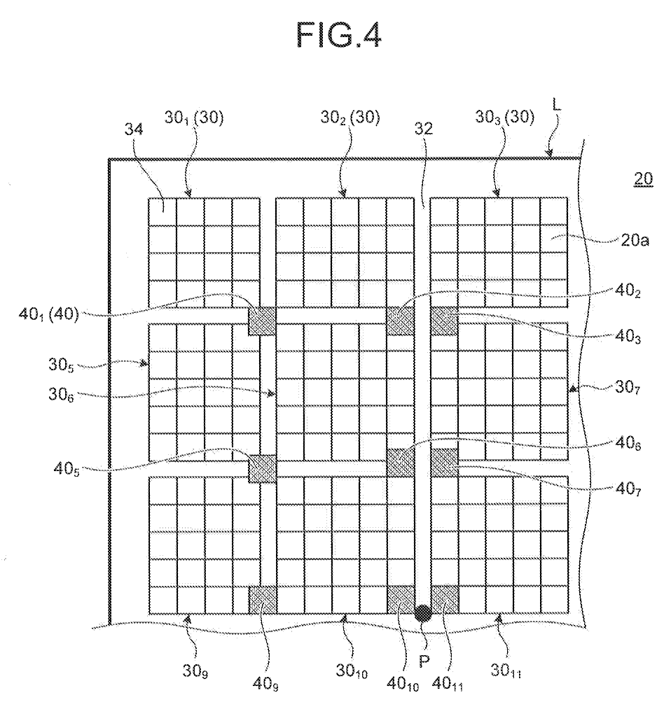

FIG. 4 is a schematic diagram in which a part of the photodetecting element 20 illustrated in FIG. 3 is enlarged. The pixel regions 30 each have the configuration of a plurality of photodetection portions 34 being arrayed in a matrix form. That is, the photodetecting element 20 has the configuration in which a plurality of photodetection portions 34 are defined, as a single pixel (a single pixel region 30) and the respective pixel regions 30 are arrayed in a matrix form.

The photodetecting element 20 is provided with first electrodes 40. The first electrodes 40 are provided respectively corresponding to the pixel regions 30 (which will be detailed later).

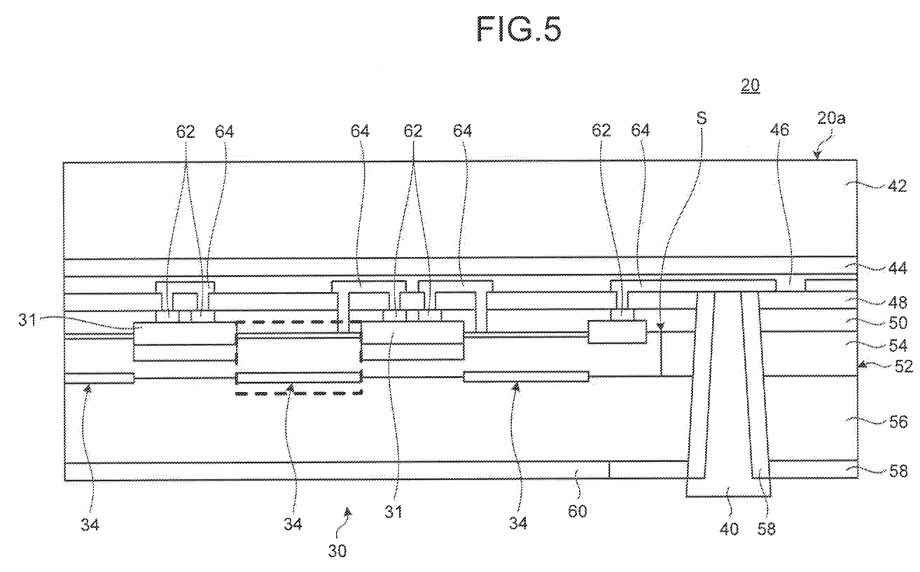

FIG. 5 is a schematic diagram illustrating an example of a cross-sectional view of the photodetecting element 20.

The photodetecting element 20 has a multilayer structure in which a glass plate 42, an adhesive layer 44, a silicon dioxide layer 46, a silicon dioxide layer 48, a silicon dioxide layer 50, a first layer 52, an N type silicon substrate 56, and a common electrode 60 are stacked together in this order.

The glass plate 42 transmits at least the light of a wavelength region that is to be detected in the photodetection portions 34. In place of the glass plate 42, scintillators may be arranged.

The adhesive layer 44 has the function of bonding together the glass plate 42 and the silicon dioxide layer 46. The silicon dioxide layer 46 is formed of a material containing silicon dioxide (SiO₂), and holds signal electrodes 64 therewithin. The silicon dioxide layer 46 contains silicon dioxide as the largest composition, for example. The signal electrodes 64 extend in a planar shape along the first plane 20a and connected to each of the photodetection portions included in the respective pixel regions 30, and outputs the signals received from the respective photodetection portions 34. The signal electrodes 64 are, for example, wiring of metal having electrical conductivity (for example, aluminum or copper).

The silicon dioxide layer 48 and the silicon dioxide layer 50 are formed of a material including silicon dioxide (SiO₂).

The first layer 52 includes the photodetection portions 34. The first layer 52 includes an N-type silicon layer 54 and the photodetection portions 34, for example. The photodetection portions 34 are arranged at positions corresponding to the inside of the respective pixel regions 30 in the first layer 52.

The photodetection portion 34 has a PN junction and is an avalanche photo-diode (APD) formed as a PN diode. The photodetection portions 34 provide continuity in a reverse-bias direction between the anode side of the photodetection portion 34 and the cathode side by avalanche breakdown which occurs by light (photons) entering the photodetecting portions 34.

As for the photodetection portions 34, a P− type semiconductor layer is formed on the N type silicon substrate 56 through epitaxial, growth of silicon, for example. Then, a dopant (for example, boron) is implanted so that a part of the P− type semiconductor layer becomes a P+ type semiconductor layer. This forms a plurality of photodetection portions 34 on the N type silicon substrate 56.

In the first layer 52, formed between the respective photodetection portions 34 are element isolation regions 31. The element isolation regions 31 are formed in a deep trench isolation structure, or a channel stopper structure by implanting dopant (for example, phosphorus). By the element isolation, the element isolation regions 31 are formed between the respective photodetection portions 34.

In the silicon dioxide layer 50, formed in the region between the photodetection portions 34 are quenching resistors 62 connected in series to the respective photodetection portions 34.

The quenching resistors 62 are in passages of electrical charge amplified at the PN junction of the respective photodetection portions 34. That is, the quenching resistors 62 are necessary to drive, in Geiger mode, the photodetection portion 34 as an APD. For the quenching resistors 62, polysilicon is used, for example.

The photodetection portion 34 is connected to the signal electrode 64 via the quenching resistor 62. Thus, a pulsed signal output from each of the photodetection portions 34 is output to the signal electrode 64 via the quenching resistor 62.

In the photodetecting element 20, the first electrodes 40 are provided. The first electrodes 40 are provided respectively corresponding to the pixel regions 30. That is, one first electrode 40 is provided corresponding to a single pixel region 30. The first electrode 40 passes through the first layer 52 in a second direction intersecting with the first plane 20a. The second direction corresponds to the direction of stacking the respective layers constituting the photodetecting element 20. One end side of the first electrode 40 in the second direction is connected to the signal electrode 64. The other end side of the first electrode 40 is connected to the signal processing circuit 22 via the signal line 23 (see FIG. 1). On the outer circumference of the lateral surface of the first electrode 40, an insulating layer 58 is provided. In the following description, the outer circumference of the lateral surface of the first electrode 40 is simply referred to as the outer circumference of the first electrode 40.

On the surface of the N type silicon substrate 56 on the side opposite to the first layer 52, the common electrode 60 is provided.

In the photodetecting element 20 in the first embodiment, out of a plurality of first electrodes 40 provided on the photodetecting element 20, the first electrodes 40, which are provided respectively corresponding to the pixel regions 30 arranged in the edge area of the first plane 20a of the photodetecting element 20, are each arranged such that at least a part of the region thereof is arranged outside of the corresponding pixel region 30.

That is, out of the first electrodes 40 provided on the photodetecting element 20, the first electrodes 40 provided respectively corresponding to the pixel regions 30 arranged in the edge area L of the first plane 20a of the photodetecting element 20, correspond to first electrodes of the invention.

The edge area of the first plane 20a of the photodetecting element 20 means, in the first plane 20a, an area that lie along the circumferential edge of the first plane 20a. Specifically, the pixel regions 30 arranged in the edge area of the first plane 20a of the photodetecting element 20 are a group of the pixel regions 30 arrayed in a single row along the circumferential edge of the first plane 20a of the photodetecting element 20.

In the following description, the pixel regions 30 arranged in the edge area of the first plane 20a of the photodetecting element 20 may simply be referred to as “the pixel regions 30 arranged in the edge area.”

With reference to FIGS. 3 and 4, the detail thereof will be described.

Out of the plurality of pixel regions 30 (pixel) region 30₁ to pixel region 30₂₄) included in the photodetecting element 20, the pixel regions arranged in the edge area L of the photodetecting element 20 correspond to the pixel regions 30₁ to 30₄, 30₅, 30₈, 30₉, 30₁₂, 30₁₃, 30₁₆, 30₁₇, 30₂₀, and 30₂₁ to 30₂₄ in FIG. 3. That is, the pixel regions 30 arranged in the edge area L are a group of pixel regions 30 arranged continuously in the edge area L of the first plane 20a of the photodetecting element 20 and arrayed in a single row in the circumferential direction of the edge area L.

In the photodetector 10 in the first embodiment, each of the first electrodes 40 (401 to 40₄, 40₅, 40₈, 40₉, 40₁₂, 40₁₃, 40₁₆, 40₁₇, 40₂₀, and 40₂₁ to 40₂₄) provided respectively corresponding to the pixel regions 30 (the pixel regions 30₁ to 30₄, 30₅, 30₈, 30₉, 30₁₂, 30₁₃, 30₁₆, 30₁₇, 30₂₀, and 30₂₁ to 30₂₄) arranged in the edge area L is arranged such that at least a part of the region thereof is outside of the corresponding one of the pixel regions 30 (the pixel regions 301 to 30₄, 30₅, 30₈, 30₉, 30₁₂, 30₁₃, 30₁₆, 30₁₇, 30₂₀, and 30₂₁ to 30₂₄).

Specifically, as illustrated in FIGS. 3 and 4, at least a part of the region of the first electrode 40₁ provided corresponding to the pixel region 30₁ arranged in the edge area L is arranged outside of the pixel region 30₁. As for each of the first electrodes 40 (40₂ to 40₄, 40₅, 40₈, 40₉, 40₁₂, 40₁₃, 40₁₆, 40₁₇, 40₂₀, and 40₂₁ to 40₂₄) provided respectively corresponding to the other pixel regions 30 arranged in the edge area L, at least a part of the region thereof is arranged outside of the corresponding one of the pixel regions 30, in the same manner.

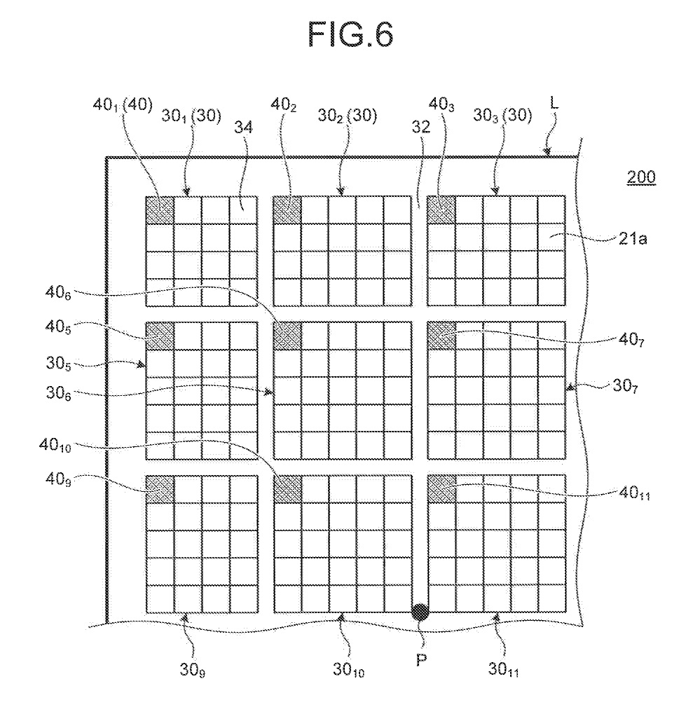

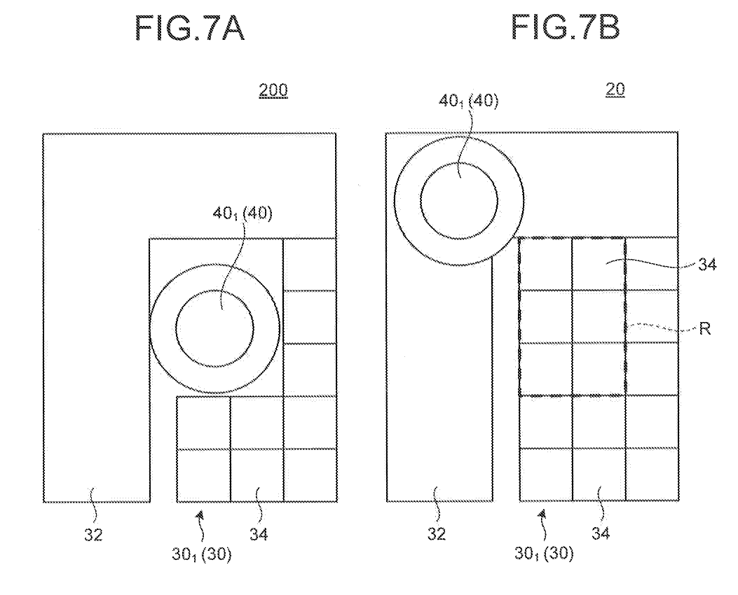

The following describes a conventional photodetecting element 200. FIG. 6 is a schematic diagram illustrating one example of the conventional photodetecting element 200. FIGS. 7A and 7B are comparison diagrams between the conventional photodetecting element 200 and the photodetecting element 20 in the first embodiment.

As illustrated in FIGS. 6 and 7A, in the conventional photodetecting element 200, the first electrodes 40 provided respectively corresponding to the pixel regions 30 included in the conventional photodetecting element 200 are arranged inside of the respective corresponding pixel regions 30.

Thus, in the conventional photodetecting element 200, on the pixel regions 30 (for example, the pixel region 30₁) arranged in the edge area L in particular, the number of photodetection portions 34 that can be arranged inside of the pixel region 30₁ tends to decrease by arranging the first electrode 40 (for example, the first electrode 40₁) inside.

In contrast, in the photodetecting element 20 in the first embodiment, as illustrated in FIG. 7B, the first electrodes 40 (for example, the first electrode 40₁) arranged respectively corresponding to the pixel regions 30 (for example, the pixel region 30₁) arranged in the edge area L are arranged outside of the pixel region 30 (for example, the pixel region 30₁). Thus, the photodetection portions 34 can be arranged in the region R that is occupied by the first electrode 40 (for example, the first electrode 40₁) inside the pixel region 30 (for example, the pixel region 30₁) arranged in the edge area L in the conventional photodetecting element 200.

Consequently, the light-receiving area of the pixel region 30 (the sum total of the light-receiving areas by a plurality of photodetection portions 34 included in that pixel region 30) arranged in the edge area L is prevented from being decreased. Thus, in the photodetecting element 20 in the first embodiment, the improvement in dynamic range can be achieved.

In the photodetector 10 in the first embodiment, by arranging the first electrodes 40 at the above-described positions, the pitch of the pixel regions 30 included in the photodetecting element 20 can have a length, shorter than twice the pitch of the first electrodes 40. In particular, the pitch of the pixel regions 30 arranged in the edge area L of the first plane 20a of the photodetecting element 20 can have a length shorter than twice the pitch of the corresponding first electrodes 40 provided.

The pitch of the pixel regions 30 means, on the first plane 20a, the shortest distance between the center of the pixel region 30₆ and the center of the adjacent pixel region 30₇. That is, the pitch of the pixel regions 30 is the shortest distance between the centers of the adjacent pixel regions 30 other than the pixel regions 30 arranged in the edge area L of the photodetecting element 20, out of a plurality of pixel regions 30 (the pixel region 30₁ to the pixel region 30₂₄) included in the photodetecting element 20. The pitch of the first electrodes 40 means the length of the first electrodes 40 on the first plane 20a. In detail, the pitch of the first electrodes 40 means the length of the first electrodes 40 in the arrow X direction (the rotational direction of the photodetector 10) on the first plane 20a.

In the conventional photodetecting element 200, the pitch of the pixel regions 30 included in the photodetecting element 20 needed to have a length of twice or longer the pitch of the first electrodes 40. In contrast, in the photodetecting element 20 in the first embodiment, the pitch of the pixel regions 30 included in the photodetecting element 20 can have a length shorter than twice the pitch of the first electrodes 40, by arranging the first electrodes 40 at the above-described positions. In particular, the pitch of the pixel regions 30 constituting the circumferential-edge pixel regions can be a length shorter than twice the pitch of the first electrodes 40 provided correspondingly.

The pitch of the first electrodes 40 is the same in both the conventional photodetecting element 200 and the photodetecting element 20 in the first embodiment. Hence, in the photodetector 10 in the first embodiment, the increase in the number of photodetection portions 34 included in the pixel region 30 can be achieved. In the photodetector 10 in the first embodiment, the increase in the number of photodetection portions 34 included in the pixel region 30 constituting the circumferential-edge pixel regions in particular can be achieved.

It is preferable that the first electrode 40 provided corresponding to the pixel region 30 arranged in the edge area L of the first plane 20a of the photodetecting element 20 be arranged such that at least a part of the region thereof is outside of that pixel region 30, and on the center side of the first plane 20a with respect to that pixel region 30.

That is, as illustrated in FIGS. 3 and 4, it is preferable that the first electrode 40₁ provided corresponding to the pixel region 30 (for example, the pixel region 30₁) arranged in the edge area L be arranged such that at least a part of the region thereof is outside of the pixel region 30₁, and on the center P side with respect to the pixel region 30₁. As for each of the first electrodes 40 provided respectively corresponding to the other pixel regions 30 arranged in the edge area L, it is preferable to be arranged in the same manner such that sit least a part of the region thereof is outside of the corresponding pixel region 30, and on the center P side.

The first electrode 40 that is provided corresponding to the pixel region 30 arranged in the edge area L of the first plane 20a of the photodetecting element 20 may be arranged such that at least a part of the region thereof is positioned outside of that pixel region 30, and inside of the other adjacent pixel region 30 on the center P side of the first plane 20a with respect to that pixel region 30.

For example, as illustrated in FIGS. 3 and 4, the first electrode 40₁ that is provided corresponding to the pixel region 30 (for example, the pixel region 30₁) arranged in the edge area L may be arranged such that at least a part of the region thereof is outside of the pixel region 30₁, and inside of the pixel region 30₆ that is adjacent on the center P side with respect to the pixel region 30₁. As for each of the first electrodes 40 provided respectively corresponding to the other pixel regions 30 arranged in the edge area L, it may be arranged in the same manner such that at least a part of the region thereof is outside of the corresponding pixel region 30, and inside of the other pixel region 30 that is adjacent on the center P side.

As for each of the first electrodes 40 provided respectively corresponding to the pixel regions 30 other than the pixel regions 30 arranged in the edge area L, it may be arranged in the same manner such that at least a part of the region thereof is outside of the corresponding pixel region 30.

Furthermore, as illustrated in FIG. 3, it is most preferable that the positions of the first electrodes 40 provided respectively corresponding to all of the pixel regions 30 included in the photodetecting element 20 be adjusted such that the number of photodetection portions 34 included in each of all of the pixel regions 30 included in the photodetecting element 20 is the same.

In the photodetecting element 20 in the first embodiment, it is preferable that a terminal portion of the PN junction in the photodetection portion 34 be not in contact with the first electrode 40 or with the insulating layer 58 provided along the outer circumference of the first electrode 40.

As illustrated in FIG. 3, in the photodetecting element 20 in the first embodiment, a terminal portion S of the PN junction is not in contact with the first electrode 40 or with the insulating layer 58 provided on the outer circumference of the first electrode 40. In other words, in the first embodiment, the terminal portion S of the PN junction is arranged to be in contact, via the N type silicon layer 54, with the insulating layer 58 that is provided on the outer circumference of the first electrode 40.

Thus, the outer circumference of the first electrode 40 is not in contact with the terminal portion S of the PN junction, and is in contact with N type regions (the N type silicon substrate 56 and the N type silicon layer 54) via the insulating layer 58.

For example, it is sufficient that the outer circumference of the first electrode 40 is in an N type region by diffusing N type impurities in a P type epitaxial-layer in the circumference of the first electrode 40. Consequently, the terminal portion S of the PN junction can be changed to a substrate surface side (the first plane 20a side) of stable surface characteristics as compared with the outer circumferential surface of the first electrode 40.

It is sufficient that the terminal portion S is not in contact with the outer circumference of the first electrode 40 or the insulating layer 58 provided on the outer circumference of the first electrode 40, and thus in place of the N type region illustrated in FIG. 5, it may be in contact with a P type region.

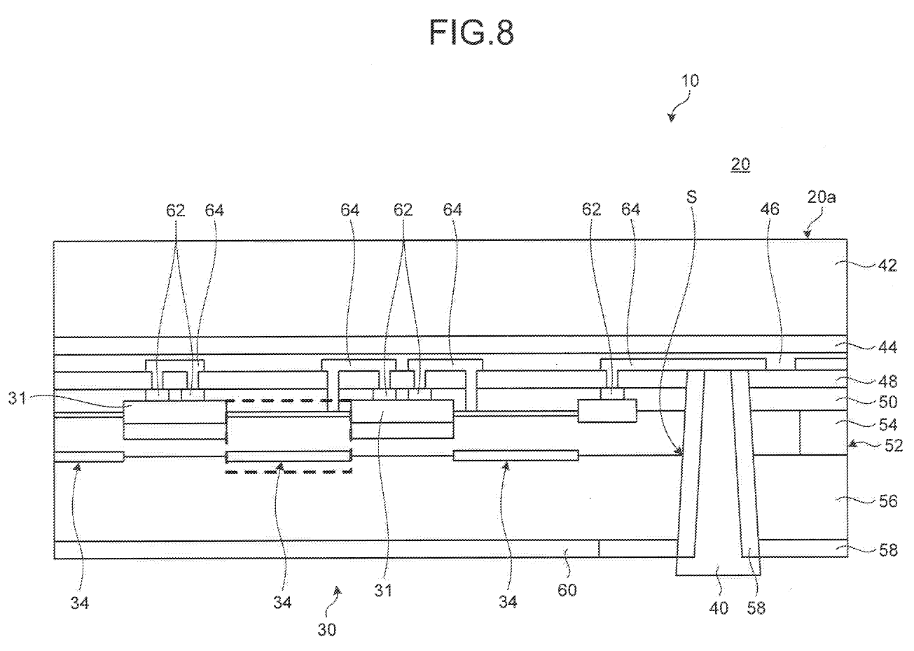

FIG. 8 is a schematic diagram illustrating a condition in which the terminal portion S is in contact with the outer circumference of the first electrode 40 or with the insulating layer 58 provided on the outer circumference of the first electrode 40.

The outer circumferential surface of the first electrode 40 is unstable in surface characteristics, as compared with those of the silicon dioxide layer 50 and the N type silicon substrate 56. Thus, if the terminal portion S is in contact with the first electrode 40 or with the insulating layer 58 provided on the outer circumference of the first electrode 40 (see FIG. 8), a dark leakage current in the PN junction may increase,

In contrast, if the terminal portion S is not in contact with the first electrode 40 or with the insulating layer 58 provided on the outer circumference of the first electrode 40 (see FIG. 5), the terminal portion S of the PN junction can be the substrate surface side (the first plane 20a side) that is stable in surface characteristics as compared with the outer circumferential surface of the first electrode 40.

Consequently, when the terminal portion S is not in contact with the first electrode 40 or with the insulating layer 58 provided on the outer circumference of the first electrode 40, noise due to the dark leakage current of the photodetecting element 20 can be reduced, and thus not being in contact is preferable.

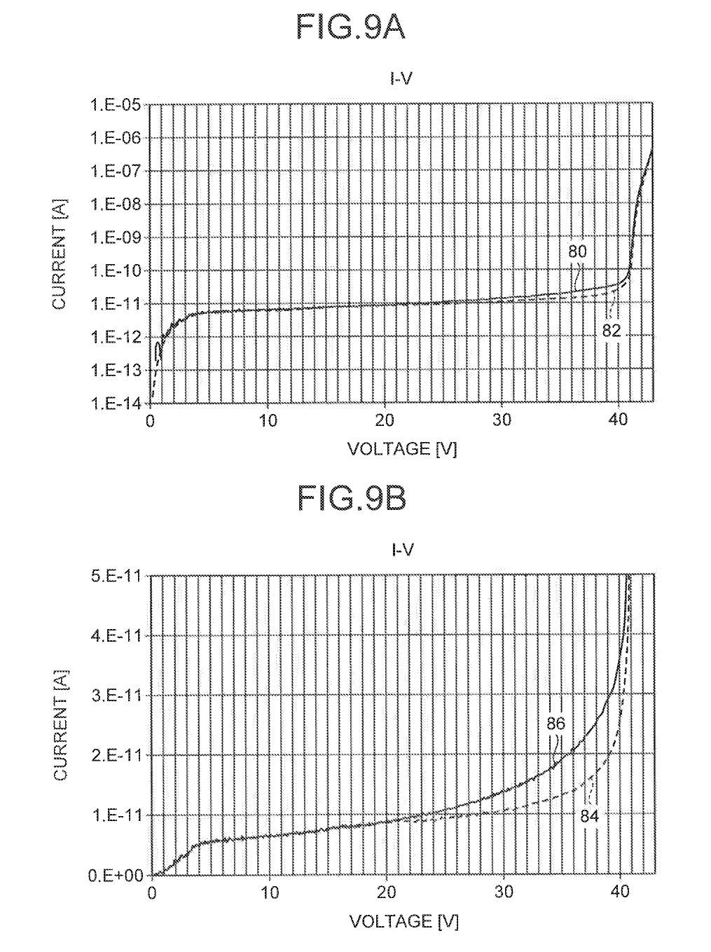

FIGS. 9A and 9B are explanatory charts illustrating the electrical characteristics of the photodetecting element 20 in the first embodiment. A line drawing 82 and a line drawing 84 indicate the case of the terminal portion S being not in contact with the first electrode 40 or with the insulating layer 58 provided on the outer circumference of the first electrode 40. A line drawing 80 and a line drawing 86 indicate the case of the terminal portion S being in contact with the first electrode 40 or with the insulating layer 58 provided on the outer circumference of the first electrode 40.

As illustrated in FIGS. 9A and 9B, when the terminal portion S is not in contact with the first electrode 40 or with the insulating layer 58 provided on the outer circumference of the first electrode 40, as compared with a case when the terminal portion S is in contact, the dark leakage current was reduced at voltages lower than the breakdown.

It is conceivable that, because the outer circumferential surface of the first electrode 40 is formed by reactive ion etching (RIE), the surface defect density is high. Hence, it is conceivable that the leakage current increases when the terminal portion S contacts with the outer circumferential surface of the first electrode 40. Meanwhile, providing the terminal portion S so as not to be in contact with the outer circumferential surface of the first electrode 40 or with the insulating layer 58 provided on the first electrode 40 can reduce the dark leakage current.

As in the foregoing, the photodetector 10 in the first embodiment includes the photodetecting element 20 and the first electrodes 40. In the photodetecting element 20, a plurality of pixel regions 30 including a plurality of photodetection portions 34 that detect light are arrayed on the first plane 20a on which the light is incident. The first electrodes 40 (the first electrodes 40₁, 40₂, 40₃, 40₅, and 40₉) pass through the first layer 52 including the photodetection portions 34 in the second direction that intersects with the first plane 20a; are provided respectively corresponding to the pixel regions 30 (the pixel regions 30₁, 30₂, 30₃, 30₅, and 30₉) arranged in the edge area L of the first plane 20a of the photodetecting element 20; and are each arranged such that at least a part of the region thereof is arranged outside of the corresponding one of the pixel regions 30 (the pixel regions 30₁, 30₂, 30₃, 30₅, and 30₉).

As just described, in the photodetector 10 in the first embodiment, the first electrodes 40 provided respectively corresponding to the pixel regions 30 arranged in the edge area L of the first plane 20a of the photodetecting element 20 are arranged, outside of the respective corresponding pixel regions 30. Thus, the photodetection portions 34 can be arranged in the region R that is occupied by the first electrode 40 inside the pixel region 30 arranged in the edge area L of the first plane 20a of the photodetecting element 20 in the conventional photodetecting element 200.

Hence, the sum total of the light-receiving areas of a plurality of photodetection portions 34 included in the pixel region 30 arranged in the edge area L of the first plane 20a of the photodetecting element 20 is prevented from being decreased.

Consequently, in the photodetector 10 in the first embodiment, the improvement in dynamic range can be achieved.

### Second Embodiment

In the photodetecting element 20 in the first embodiment, an embodiment of coupling the signal electrodes 64 to the first electrode 40 that is a through-hole electrode has been exemplified. In a second embodiment, in addition, the common electrode 60 is connected to a through-hole electrode (a second electrode).

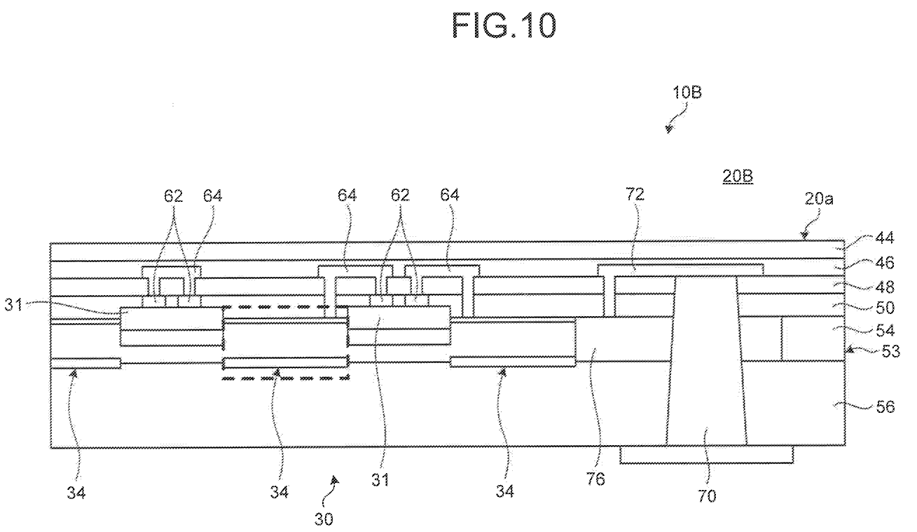

FIG. 10 is a schematic diagram of a photodetector 10B according to the second embodiment. The photodetector 10B is the same as the photodetector 10 in the first embodiment with only the exception of including a photodetecting element 20B in place of the photodetecting element 20 (see FIGS. 1, 2A, and 2B). Thus, the portions having the same functions as those of the photodetector 10 in the first embodiment will be given the same reference numerals or symbols, and their detailed explanations may be omitted.

The photodetecting element 20B has the same configuration as that of the photodetecting element 20 in the first embodiment, with the exception of further providing a common electrode 72 inside the silicon dioxide layer 46 and coupling the common electrode 72 to a second electrode 70.

Although the depiction is omitted in FIG. 10, the configuration and arrangement of the first electrode 40 are the same as those in the first embodiment.

The photodetecting element 20B is of a layer-stacked structure in which the adhesive layer 44, the silicon dioxide layer 46, the silicon dioxide layer 48, the silicon dioxide layer 50, a first lawyer 53, the N type silicon layer 54, and the N type silicon substrate 56 are stacked in the foregoing order. The adhesive layer 44, the silicon dioxide layer 46, the silicon dioxide layer 48, the silicon dioxide layer 50, the N type silicon layer 54, and the N type silicon substrate 56 are the same as those of the photodetecting element 20 in the first embodiment.

The first layer 53 is a layer that includes the photodetection portions 34. The first layer 53 includes the N type silicon layer 54, the photodetection portions 34, and a high-concentration N type layer 76, for example. The photodetection portions 34 are arranged at positions corresponding to the inside of the respective pixel regions 30 in the first layer 53.

In the first layer 53, the element isolation regions 31 are formed between the respective photodetection portions 34.

The photodetection portions 34 are each connected to the first electrode 40 (depiction omitted in FIG. 10) via the quenching resistors 62 and the signal electrodes 64. The arrangement of the first electrode 40 is the same as that in the first embodiment.

The high-concentration N type layer 76 is connected to the common electrode 72. The high-concentration N type layer 76 can be formed by manufacturing technologies such as ion implantation. Consequently, the contact between the common electrode 72 and the high-concentration N type layer 76 can be good ohmic contact.

The common electrode 72 is connected in common to the photodetection portions 34 included in each of a plurality of pixel regions 30 provided on the photodetecting element 20B. The common electrode 72 is further connected to the second electrode 70.

The second electrode 70 is an electrode that passes through the first layer 53 in the second direction (i.e., the direction of stacking the respective layers constituting the photodetecting element 20B). In the second embodiment, the second electrode 70 is arranged outside of the pixel regions 30 arranged in the edge area L.

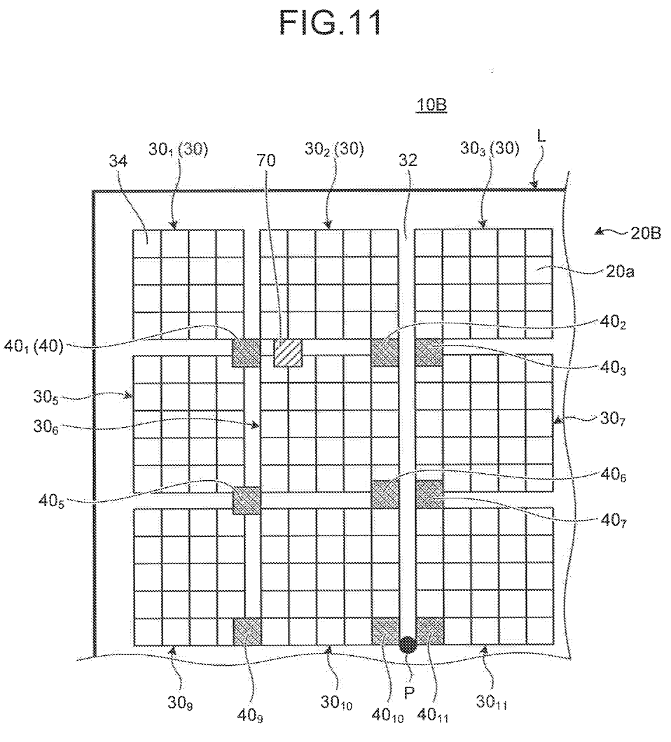

FIG. 11 is a plan view of the photodetecting element 20B. As illustrated in FIG. 11, as the same as that of the first embodiment, at least a part of the region of the first electrode 40 that is provided corresponding to the pixel region 30 arranged in the edge area L is arranged outside of that pixel region 30.

That is, in the photodetecting element 20B in the second embodiment, as the same as that of the first embodiment, each of the first electrodes 40 (40₁ to 40₃, 40₅, and 40₉) that is provided respectively corresponding to the pixel regions 30 (the pixel regions 30₁ to 30₃, 30₅, and 30₉) arranged in the edge area L is arranged such that at least a part of the region thereof is outside of the corresponding one of the pixel regions 30 (the pixel regions 30₁ to 30₃, 30₅, and 30₉).

In the photodetecting element 20B in the second embodiment, the second electrode 70 is further arranged outside of the pixel regions 30 (the pixel regions 30₁ to 30₃, 30₅, 30₉) arranged in the edge area L.

Consequently, in the photodetecting element 20B in the second embodiment, it becomes possible to make contact with the common electrode 72 at the surface of the high-concentration N type layer 76.

Meanwhile, in the case that the second electrode 70 is not provided, a silicon substrate is thin-layered to form the N type silicon substrate 56 after the pattern structure of the signal electrodes 64 is formed, and afterward, the common electrode is formed. Thus, it is difficult to form a high-concentration N type layer on the reverse side (light emitting side) of the photodetecting element 20B, and the contact resistance between the common electrode and the N type silicon substrate 56 is high.

In contrast, in the photodetecting element 20B provided with the second electrode 70 in the second embodiment, it is possible to make contact with the common electrode 72 at the surface of the high-concentration N type layer 76.

Consequently, in the photodetector 10B provided with the photodetecting element 20B in the second embodiment, it can yield good ohmic contact between the common electrode 72 and the high-concentration N type layer 76, in addition to the advantageous effects of the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photodetector comprising:
a photodetecting element in which a plurality of pixel regions including a plurality of photodetection portions that detects light are arrayed on a first plane on which the light is incident; and
first electrodes that
pass through a first layer including the photodetection portions in a second direction intersecting with the first plane,
are provided respectively corresponding to the pixel regions arranged in an edge area of the first plane of the photodetecting element, and
are each arranged such that at least a part of a region thereof is arranged outside of the corresponding pixel region.

2. The photodetector according to claim 1, wherein the first electrode is arranged such that at least a part of the region thereof is outside of the corresponding pixel region and on a center side of the first plane with respect to the corresponding pixel region.

3. The photodetector according to claim 1, wherein the first electrode is arranged such that at least a part of the region thereof is outside of the corresponding pixel region and positioned inside of another pixel region adjacent on a center side of the first plane with respect to the corresponding pixel region.

4. The photodetector according to claim 1, wherein
the photodetection portion includes a PN junction, and
a terminal portion of the PN junction is not in contact with the first electrode or with an insulation layer provided along an outer circumference of she first electrode.

5. The photodetector according to claim 1, further comprising a second electrode that
passes through the first layer in the second direction,
is connected to a common electrode that is connected in common to the photodetection portions respectively included in the pixel regions, and
is arranged outside of the pixel regions arranged in the edge area of the first plane of the photodetecting element.

6. The photodetector according to claim 1, wherein the first electrode is connected to signal electrodes that output signals output from the photodetection portions included in the pixel region.
